(19) United States
(12) Patent Application Publication
(10) Pub. No.: US 2025/0275090 A1
(43) Pub. Date: Aug. 28, 2025

(54) LEAK-PROOF DEVICE, LIQUID COOLING SYSTEM AND ELECTRONIC DEVICE

(71) Applicant: Wiwynn Corporation, New Taipei City (TW)

(72) Inventors: Cheng-An Chen, New Taipei City (TW); TZU-TING WANG, New Taipei City (TW)

(21) Appl. No.: 18/915,587

(22) Filed: Oct. 15, 2024

(30) Foreign Application Priority Data
Feb. 27, 2024 (TW) 113106935

(51) Int. Cl. H05K 7/20

(52) U.S. Cl. CPC H05K 7/20272

(57) ABSTRACT

A leak-proof device is configured to be mounted on a coupling portion of a pipe. The leak-proof device includes an absorbent layer, a leak detector and a confined layer. The absorbent layer is configured to be disposed on the coupling portion of the pipe. The leak detector is in contact with the absorbent layer. The confined layer is configured to surround and wrap the absorbent layer and a part of the leak detector and be fixed to the pipe.

### CROSS-REFERENCE TO RELATED APPLICATIONS

This non-provisional application claims priority under 35 U.S.C. § 119(a) on Patent Application No(s). 113106935 filed in Taiwan, R.O.C. on Feb. 27, 2024, the entire contents of which are hereby incorporated by reference.

### TECHNICAL FIELD

The disclosure relates to a leak-proof device, a liquid cooling system and an electronic device.

### BACKGROUND

In order to effectively dissipate heat generated by a powerful electronic device (e.g., a server), the electronic device is cooled by a liquid cooling manner. The liquid cooling manner requires to arrange pipes in the electronic device, but leakage may occur at the places where the pipes are assembled with joins of a manifold or a liquid cooling plate.

For detecting the leakage, a leak detection band is wrapped at a place where a pipe is assembled with a joint. However, the leak detection band merely can detect whether the leakage occurs at the place where the pipe is assembled with the joint, but is unable to hold the leaking liquid, such that the leaking liquid may drop on electronic components (e.g., a motherboard) in the electronic device. If personnel do not turn off the electronic device or deal with the leaking liquid immediately, the leaking liquid may easily damage the electronic components. Accordingly, how to solve the aforementioned issue is one of the crucial topics in this field.

### SUMMARY

One embodiment of the disclosure provides a leak-proof device. The leak-proof device is configured to be mounted on a coupling portion of a pipe. The leak-proof device includes an absorbent layer, a leak detector and a confined layer. The absorbent layer is configured to be disposed on the coupling portion of the pipe. The leak detector is in contact with the absorbent layer. The confined layer is configured to surround and wrap the absorbent layer and a part of the leak detector and be fixed to the pipe.

Another embodiment of the disclosure provides a liquid cooling system. The liquid cooling system includes a liquid cooling device, a pipe and a leak-proof device. The liquid cooling device has a joint. The pipe has a coupling portion configured to be assembled with the joint. The leak-proof device includes an absorbent layer, a leak detector and a confined layer. The absorbent layer is configured to be disposed at a place where the coupling portion of the pipe is assembled with the joint of the liquid cooling device. The leak detector is configured to be in contact with the absorbent layer. The confined layer configured to surround and wrap the absorbent layer and a part of the leak detector and be fixed to the pipe and the joint.

Still another embodiment of the disclosure provides an electronic device. The electronic device includes a liquid cooling system, a motherboard and a baseboard management controller. The liquid cooling system includes a liquid cooling device, a pipe and a leak-proof device. The liquid cooling device has a joint. The pipe has a coupling portion configured to be assembled with the joint of the liquid cooling device. The leak-proof device includes an absorbent layer, a leak detector and a confined layer. The absorbent layer is configured to be disposed at a place where the coupling portion of the pipe is assembled with the joint of the liquid cooling device. The leak detector is configured to be in contact with the absorbent layer. The confined layer is configured to surround and wrap the absorbent layer and a part of the leak detector and be fixed to the pipe and the joint. The leak detector is electrically connected to the baseboard management controller via the motherboard, and the leak detector is configured to transmit a leak signal to the baseboard management controller via the motherboard when detecting that the absorbent layer absorbs a liquid leaking from the coupling portion of the pipe.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a block diagram of an electronic device according to a first embodiment of the disclosure;

FIG. 2 is a partial perspective view of a liquid cooling system and a motherboard in FIG. 1;

FIG. 3 is a partial perspective view of a leak-proof device in FIG. 1;

FIGS. 4 to 5 are schematic views showing installation of the leak-proof device in FIG. 2 on a pipe and a joint;

FIG. 6 is a cross-sectional view of the leak-proof device taken along a line 6-6 in FIG. 5 when the leak-proof device is installed on the pipe;

FIG. 7 is a cross-sectional view of the leak-proof device taken along a line 7-7 in FIG. 5 when the leak-proof device is installed on the pipe;

FIG. 8 is a schematic view of the leak-proof device, the pipe and the point in FIG. 5 when a leakage occurs between the pipe and the joint;

FIG. 9 is a partial perspective view of a liquid cooling system according to a second embodiment of the disclosure;

FIG. 10 is a partial perspective view of a liquid cooling system according to a third embodiment of the disclosure;

FIG. 11 is a cross-sectional view of a leak-proof device according to a fourth embodiment of the disclosure when the leak-proof device is installed on the pipe;

FIG. 12 is a cross-sectional view of a leak-proof device according to a fifth embodiment of the disclosure when the leak-proof device is installed on the pipe; and

FIG. 13 is a cross-sectional view of a leak-proof device according to a sixth embodiment of the disclosure when the leak-proof device is installed on the pipe.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

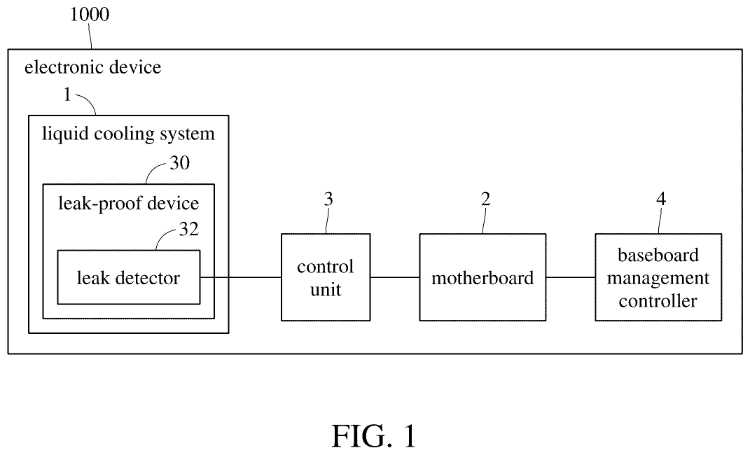

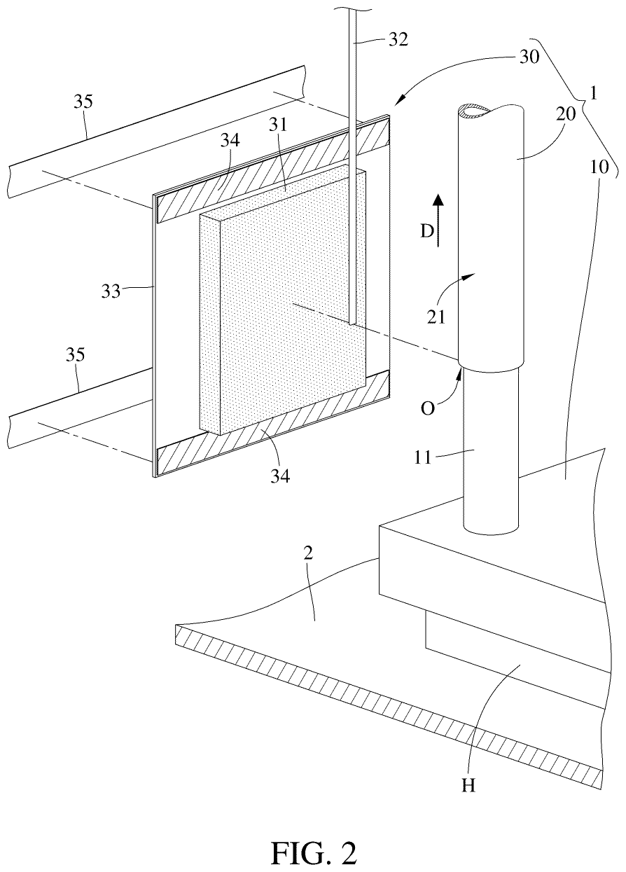

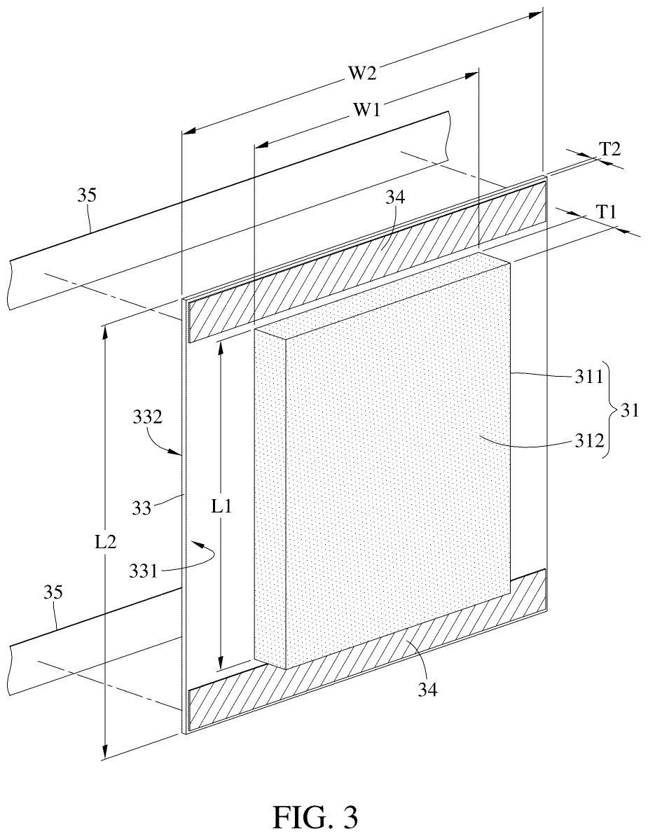

Referring to FIGS. 1 to 3, FIG. 1 is a block diagram of an electronic device according to a first embodiment of the disclosure, FIG. 2 is a partial perspective view of a liquid cooling system and a motherboard in FIG. 1, and FIG. 3 is a partial perspective view of a leak-proof device in FIG. 1.

In this embodiment, the electronic device 1000 is, for example, a server. The electronic device 1000 includes a liquid cooling system 1, a motherboard 2, a control unit 3 and a baseboard management controller 4. The control unit 3 and the baseboard management controller 4 are, for example, disposed on the motherboard 2 and are electrically connected to the motherboard 2. The liquid cooling system 1 includes a liquid cooling device 10, a pipe 20 and a leak-proof device 30.

The liquid cooling device 10 is, for example, a liquid cooling plate, and is thermally coupled to a heat source H on the motherboard 2. The heat source H is, for example, a CPU or a GPU. The liquid cooling device 10 has a joint 11. The pipe 20 is, for example, a round pipe and has a coupling portion 21, and the coupling portion 21 has an opening O. The joint 11 of the liquid cooling device 10 is, for example, inserted into the opening O of the coupling portion 21 of the pipe 20, such that liquid can flow between the pipe 20 and the liquid cooling device 10.

The leak-proof device 30 is configured to be disposed at a place where the coupling portion 21 of the pipe 20 is assembled with the joint 11 of the liquid cooling device 10. The leak-proof device 30 includes an absorbent layer 31, a leak detector 32 and a confined layer 33. In addition, the leak-proof device 30 may further include two adhesive layers 34 and two fasteners 35.

The absorbent layer 31 includes a base portion 311 and a plurality of absorbent particles 312. The base portion 311 is, for example, a sponge. The base portion 311 is configured to be disposed at the place where the coupling portion 21 of the pipe 20 is assembled with the joint 11 of the liquid cooling device 10. The base portion 311 is, for example, a rectangular body. A length L1 of the base portion 311 extends along an extension direction D (shown in FIG. 2) of the pipe 20 and falls within a range from 1 to 3 times of a circumference of the pipe 20. A width W1 of the base portion 311 is, for example, equal to the circumference of the pipe 20, and a thickness T1 of the base portion 311 falls within a range from 0.5 cm to a half of the circumference of the pipe 20. The absorbent particles 312 are, for example, sodium polyacrylate, and are disposed in the base portion 311. Assuming that the length L1, the width W1 and the thickness T1 of the base portion 311 are respectively 2 cm, 1 cm and 0.5 cm, and the base portion 311 is fully provided with the absorbent particles 312, the absorbent layer 31 may absorb more than 100 ml of liquid.

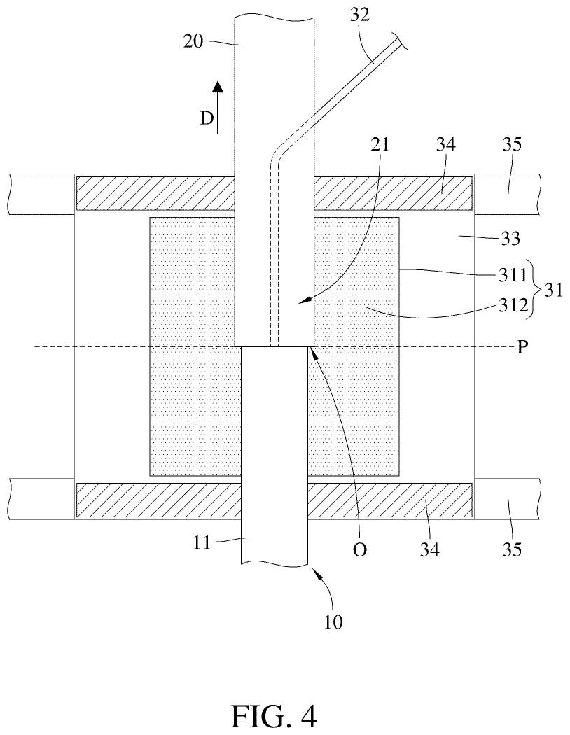

The leak detector 32 is, for example, a leak detection band or rope, and includes a cotton rope (not shown) and two conductors (not shown) disposed in the cotton rope. The leak detector 32 is configure to be in contact with the base portion 311 of the absorbent layer 31, and one end of the leak detector 32 extends to a plane P (shown in FIG. 4) where the opening O of the coupling portion 21 of the pipe 20 is located. The leak detector 32 is, for example, electrically connected to the control unit 3, and is electrically connected to the motherboard 2 via the control unit 3.

Note that one end of the leak detector 32 is not restricted to being located at the plane P where the opening O of the coupling portion 21 of the pipe 20 is located, but may be modified as required. For example, in some other embodiments, one end of the leak detector may extend to a place aside the joint of the liquid cooling device, or one end of the leak detector may be merely located aside the pipe but does not exceed the plane where the opening of the coupling portion of the pipe is located. In addition, the leak detector 32 is not restricted to being electrically connected to the motherboard 2 via the control unit 3. In some other embodiments, the leak detector may be electrically connected to the motherboard directly.

The confined layer 33 is, for example, made of an elastically deformable material, such as thermoplastic polyurethane (i.e., TPU). The confined layer 33 is, for example, a rectangular body. The confined layer 33 has a first surface 331 and a second surface 332 located opposite to each other. The first surface 331 of the confined layer 33 faces the absorbent layer 31, and a length L2 and a width W2 of the confined layer 33 are greater than the length L1 and the width W1 of the base portion 311 of the absorbent layer 31. Specifically, the length L2 of the confined layer 33 extends along the extension direction D of the pipe 20 and falls within a range from 1.5 to 2.5 times of the length L1 of the base portion 311 of the absorbent layer 31. In the extension direction D of the pipe 20, two opposite sides of the absorbent layer 31 are respectively spaced apart from two opposite sides of the confined layer 33. The width W2 of the confined layer 33 falls within a range from 1.5 to 2.5 times of the circumference of the pipe 20, and the thickness T2 of the confined layer 33 falls within a range from 0.01 cm to 0.3 cm.

The two adhesive layers 34 are, for example, acrylic adhesive. The two adhesive layers 34 are respectively disposed at two opposite sides of the first surface 331 of the confined layer 33 in the extension direction D of the pipe 20, and the two adhesive layers 34 are configured to be respectively adhered on the coupling portion 21 of the pipe 20 and the joint 11 of the liquid cooling device 10.

The two fasteners 35 are, for example, adhesive tapes. The two fasteners 35 are respectively disposed at two opposite sides of the second surface 332 of the confined layer 33 in the extension direction D of the pipe 20.

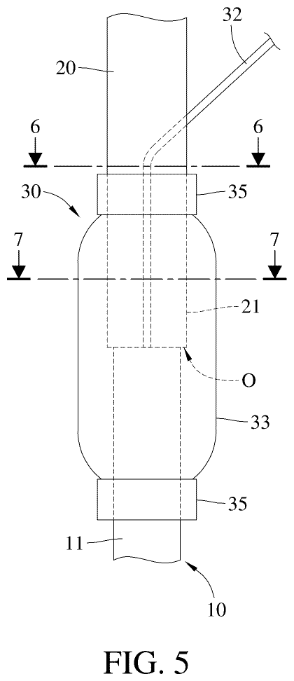

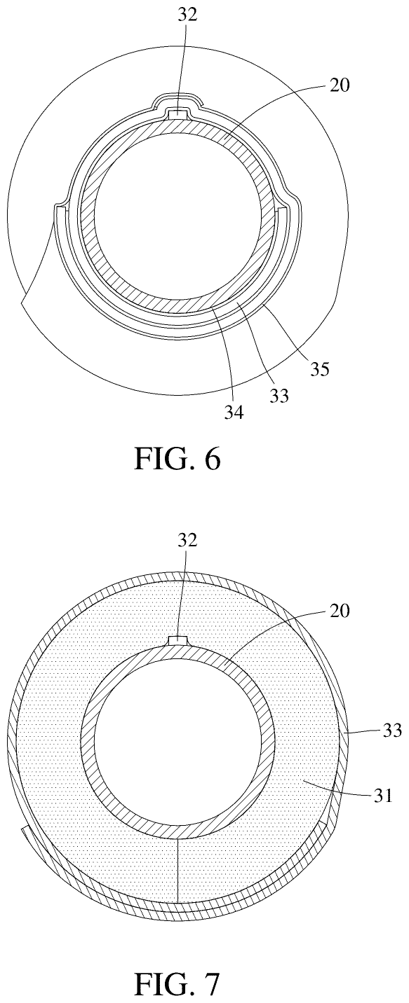

Then, the following descriptions will introduce the installation of the leak-proof device 30 to the coupling portion 21 of the pipe 20 and the joint 11 of the liquid cooling device 10. Referring to FIGS. 4 to 7, FIGS. 4 to 5 are schematic views showing installation of the leak-proof device in FIG. 2 on a pipe and a joint, FIG. 6 is a cross-sectional view of the leak-proof device taken along a line 6-6 in FIG. 5 when the leak-proof device is installed on the pipe, and FIG. 7 is a cross-sectional view of the leak-proof device taken along a line 7-7 in FIG. 5 when the leak-proof device is installed on the pipe. The first step is to allow the absorbent layer 31 and the leak detector 32 to be located at one side of the confined layer 33 where the first surface 331 (e.g., shown in FIG. 3) faces. Then, the second step is to make the two adhesive layers 34 disposed on the first surface 331 of the confined layer 33 respectively surround and adhere on the coupling portion 21 of the pipe 20 and the joint 11 of the liquid cooling device 10, and make the two fasteners 35 fasten two opposite sides of the confined layer 33 on the coupling portion 21 of the pipe 20 and the joint 11 of the liquid cooling device 10, such that the absorbent layer 31 and a part of the leak detector 32 are attached at the place where the coupling portion 21 of the pipe 20 is assembled with the joint 11 of the liquid cooling device 10.

Then, referring to FIGS. 3, 4 and 8, FIG. 8 is a schematic view of the leak-proof device, the pipe and the point in FIG. 5 when a leakage occurs between the pipe and the joint.

When a leakage occurs at the place where the coupling portion 21 of the pipe 20 is assembled with the joint 11 of the liquid cooling device 10, the liquid leaks from the opening O of the coupling portion 21 of the pipe 20 and is absorbed by the absorbent layer 31. After the liquid is absorbed by the absorbent layer 31, the liquid spreads in the absorbent layer 31 so as to wet the leak detector 32. As a result, the liquid conducts the two conductors (not shown) of the leak detector 32 so as to generate a leak signal, and the leak signal is transmitted to the baseboard management controller 4 via the control unit 3 and the motherboard 2. After the baseboard management controller 4 receives the leak signal, the baseboard management controller 4 may, for example, perform processes, such as notifying a maintainer and then turning off the electronic device 1000 after a period of time (e.g., 5 seconds).

In this embodiment, the confined layer 33 of the leak-proof device 30 is configured to (e.g., hermetically) surround and wrap the absorbent layer 31 and a part of the leak detector 32 and be fixed on the pipe 20, such that the confined layer 33 can hold the liquid leaking from the place where the coupling portion 21 of the pipe 20 and the joint 11 of the liquid cooling device 10 for preventing the liquid from damaging electronic components (e.g., the motherboard 2).

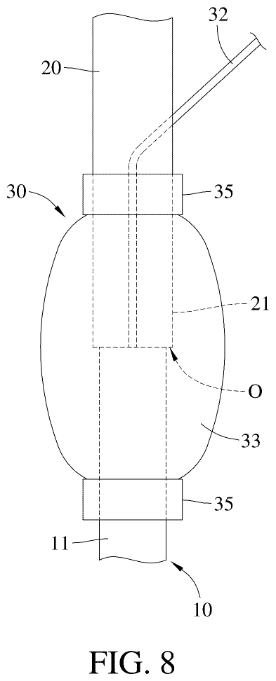

In addition, the confined layer 33 is made of an elastically deformable material, which enables the confined layer 33 to expand as shown in FIG. 8 so as to hold more liquid leaking from the place where the coupling portion 21 of the pipe 20 and the joint 11 of the liquid cooling device 10. Note that the confined layer 33 is not restricted to being made of the elastically deformable material but may be made of other suitable material as required. On the other hand, the thickness of the confined layer 33 may be modified according to the desired elasticity and is not restricted to be falling within the aforementioned range.

On the other hand, in the extension direction D of the pipe 20, the length L2 of the confined layer 33 is greater than the length L1 of the absorbent layer 31, and two opposite sides of the absorbent layer 31 are respectively spaced apart from two opposite sides of the confined layer 33, and the width W2 of the confined layer 33 is greater than the width W1 of the absorbent layer 31, which enables the confined layer 33 to fully wrap the absorbent layer 31 for ensuring the leaking liquid to be held by the confined layer 33 when the amount of the leaking liquid exceeds the amount that the absorbent layer 31 can absorb.

Note that the length L2 and the width W2 of the confined layer 33 are not restricted to being greater than the length L1 and the width W1 of the absorbent layer 31. In some other embodiments, the length and the width of the confined layer may not be greater than the length and the width of the absorbent layer according to actual requirements.

In this embodiment, the width W1 of the base portion 311 of the absorbent layer 31 is equal to the circumference of the pipe 20, which enables the base portion 311 of the absorbent layer 31 exactly surround the coupling portion 21 of the pipe 20 one round. As a result, when the liquid leaks from the opening O of the coupling portion 21 of the pipe 20, the leaking liquid can be absorbed by the absorbent layer 31 immediately, such that the leak detector 32 can detect the leakage as soon as possible. Note that the width W1 of the base portion 311 of the absorbent layer 31 is not restricted to being equal to the circumference of the pipe 20. In some other embodiments, the width of the base portion of the absorbent layer may be smaller or greater than the circumference of the pipe.

In this embodiment, the absorbent particles 312 are provided in the base portion 311 of the absorbent layer 31, which can improve the absorption capacity of the absorbent layer 31. In some embodiments, when the absorption capacity of the base portion meets the requirement, the base portion may not be provided with the absorbent particles. In addition, the thickness of the absorbent layer 31 is not restricted to being falling with the aforementioned range but may be modified according to the desired absorption capacity.

In this embodiment, the confined layer 33 can hold the liquid leaking from the opening O of the coupling portion 21 of the pipe 20. Therefore, as long as one end of the leak detector 32 sticks into a spaced enclosed by the confined layer 33 and contacts the absorbent layer 31 in this space, the leakage detection can be achieved. As a result, there is no need to wrap the leak detector 32 at the place where the coupling portion 21 of the pipe 20 is assembled with the joint 11 of the liquid cooling device 10, thereby saving the material cost of the leak detector 32.

Furthermore, the confined layer 33 can hold the liquid leaking from the opening O of the coupling portion 21 of the pipe 20, and one end of the leak detector 32 sticks into a spaced enclosed by the confined layer 33 and contacts the absorbent layer 31 in this space for achieving the leakage detection, and thus there is no need to arrange the leak detector 32 around the liquid cooling device 10. Therefore, compared to a case that the leak detector is arranged around the liquid cooling device, the material cost of the leak detector 32 can be reduced. Moreover, during the installation of the liquid cooling device 10, since there is no leak detector arranged around the liquid cooling device 10, the concern about damaging the leak detector no longer exists, thereby improving the installation efficiency.

In addition, the leak-proof device 30 is fixed at the place where the coupling portion 21 of the pipe 20 and the joint 11 of the liquid cooling device 10 via the adhesive layers 34 and the fasteners 35, thereby facilitating the installation and removal of the leak-proof device 30.

Note that the leak-proof device 30 is not restricted to being fixed at the place where the coupling portion 21 of the pipe 20 is assembled with the joint 11 of the liquid cooling device 10 via the adhesive layers 34 and the fasteners 35. In some other embodiments, the leak-proof device may be fixed at the place where the coupling portion of the pipe is assembled with the joint of the liquid cooling device via the adhesive layers or the fasteners merely.

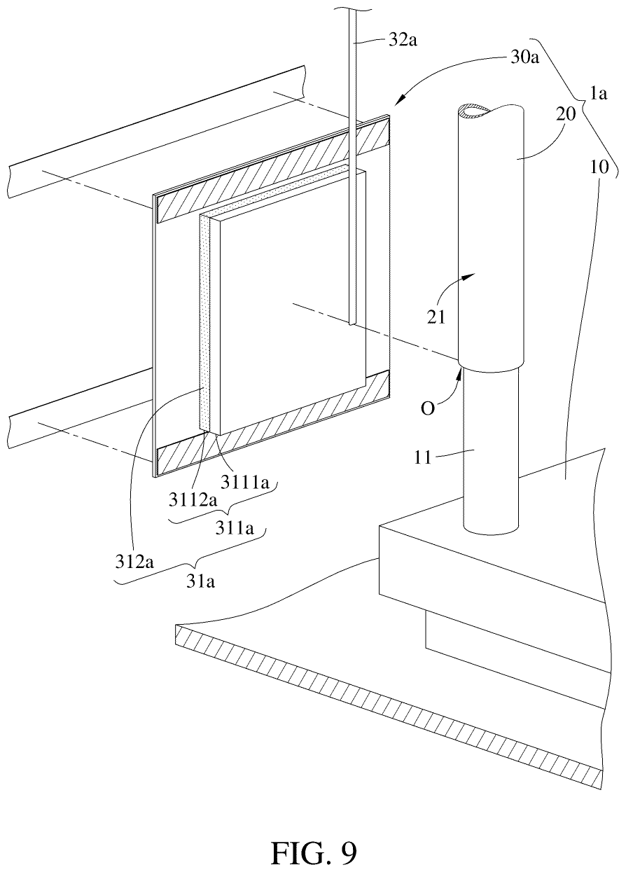

Then, referring to FIG. 9, FIG. 9 is a partial perspective view of a liquid cooling system according to a second embodiment of the disclosure.

The liquid cooling system 1a of this embodiment is similar to the liquid cooling system 1 of the previous embodiment, and the main difference between them is the structure of the absorbent layer of the leak-proof device, and thus the following paragraph mainly specifically introduces an absorbent layer 31a of a leak-proof device 30a.

In this embodiment, a density of absorbent particles 312a of the absorbent layer 31a at a place of a base portion 311a of the absorbent layer 31a located closer to the coupling portion 21 of the pipe 20 is smaller than a density of the absorbent particles 312a at other places of the base portion 311a; that is, the absorbent particles 312a in the base portion 311a of the absorbent layer 31a are less dense at the place located closer to the coupling portion 21 of the pipe 20 than other places. Specifically, the base portion 311a of the absorbent layer 31a includes an inner sub layer 3111a and an outer sub layer 3112a. The inner sub layer 3111a is surrounded by the outer sub layer 3112a and is configured to be located closer to the place where the coupling portion 21 of the pipe 20 is assembled with the joint 11 of the liquid cooling device 10 than the outer sub layer 3112a. The leak detector 32a contacts the inner sub layer 3111a, and the absorbent particles 312a of the absorbent layer 31a are disposed in the outer sub layer 3112a. When the liquid leaks from the opening O of the coupling portion 21 of the pipe 20, the liquid would spread rapidly in the inner sub layer 3111a of the base portion 311a of the absorbent layer 31a so as to be detected by the leak detector 32a. Once the liquid leaks too much, the absorbent particles 312a in the outer sub layer 3112a of the base portion 311a of the absorbent layer 31a can absorb the liquid.

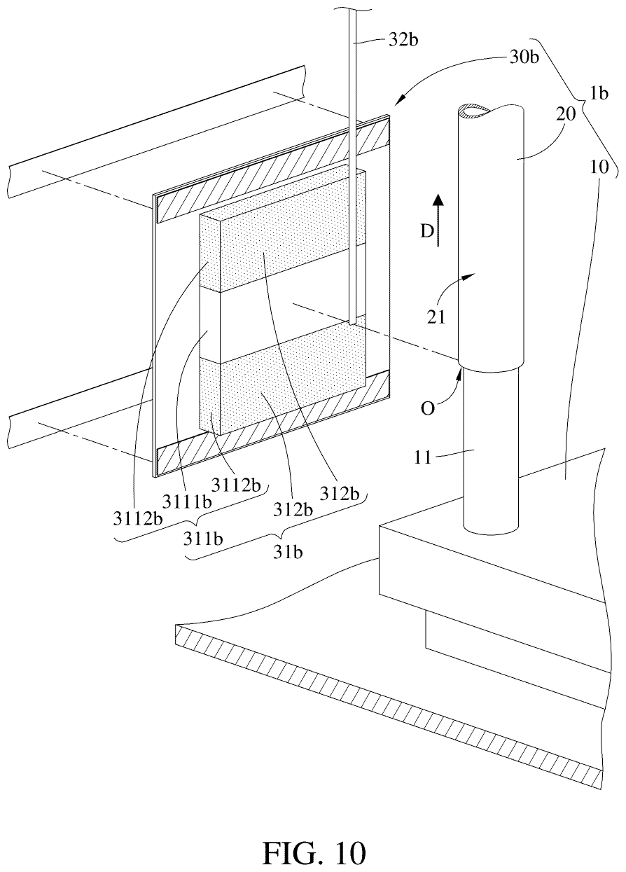

Then, referring to FIG. 10, FIG. 10 is a partial perspective view of a liquid cooling system according to a third embodiment of the disclosure.

The liquid cooling system 1b of this embodiment is similar to the liquid cooling system 1 of the previous embodiment, and the main difference between them is the structure of the absorbent layer of the leak-proof device, and thus the following paragraph mainly specifically introduces an absorbent layer 31b of a leak-proof device 30b.

In this embodiment, a density of absorbent particles 312b of the absorbent layer 31b at a place of a base portion 311b of the absorbent layer 31b located closer to the coupling portion 21 of the pipe 20 is smaller than a density of the absorbent particles 312b at other places of the base portion 311b; that is, the absorbent particles 312b in the base portion 311b of the absorbent layer 31b are less dense at the place located closer to the coupling portion 21 of the pipe 20 than other places. Specifically, the base portion 311b of the absorbent layer 31b includes a middle section 3111b and two side sections 3112b. The middle section 3111b is configured to correspond to the opening O of the coupling portion 21 of the pipe 20, and the middle section 3111b is located between and connected to the two side sections 3112b in the extension direction D of the pipe 20. One end of the leak detector 32b extends to the middle section 3111b of the base portion 311b, and the absorbent particles 312b are disposed in the side sections 3112b of the base portion 311b. When the liquid leaks from the opening O of the coupling portion 21 of the pipe 20, the liquid can rapid spread in the middle section 3111b of the base portion 311b of the absorbent layer 31b so as to be detected by the leak detector 32b. Once the liquid leaks too much, the absorbent particles 312b in the side sections 3112b of the base portion 311b of the absorbent layer 31b can absorb the liquid.

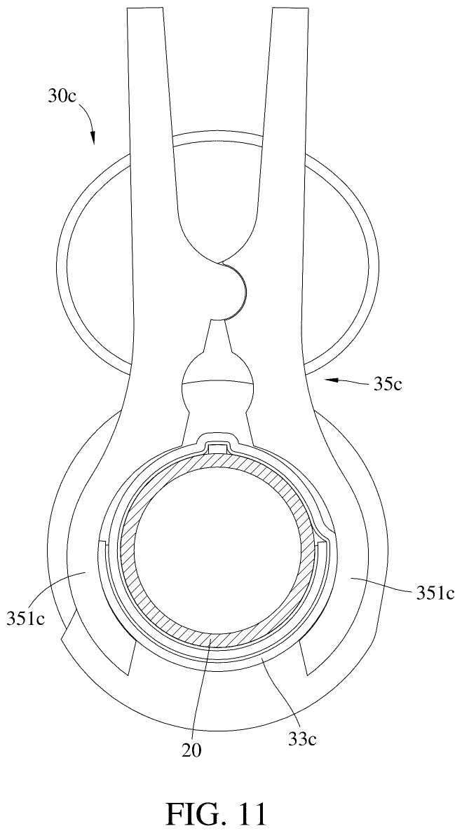

Then, referring to FIG. 11, FIG. 11 is a cross-sectional view of a leak-proof device according to a fourth embodiment of the disclosure when the leak-proof device is installed on the pipe.

The main difference between a leak-proof device 30c of this embodiment and the leak-proof devices of the previous embodiments is the structure of the fastener, and thus the follow paragraph mainly introduces a fastener 35c of the leak-proof device 30c.

In this embodiment, the fastener 35c of the leak-proof device 30c is, for example, a clamp including two curved arms 351c for fastening a confined layer 33c on the pipe 20.

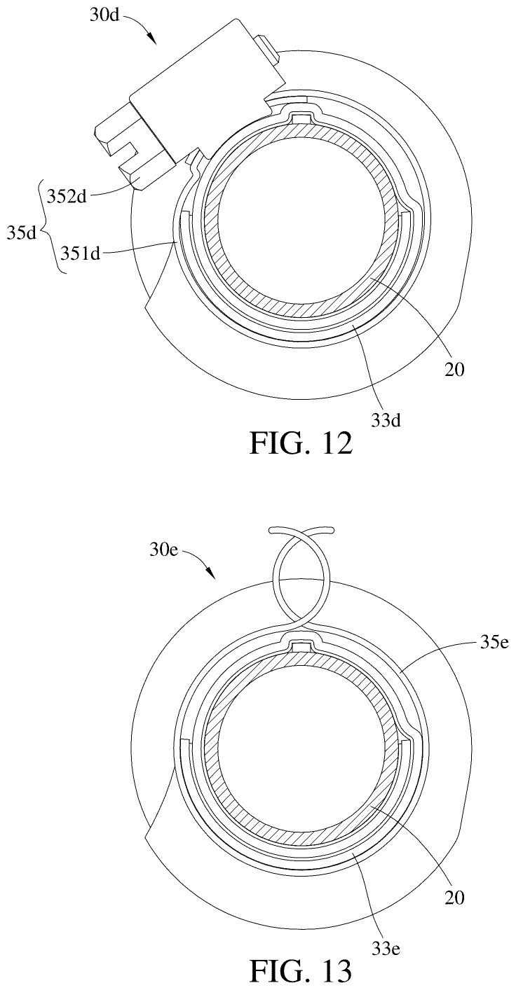

Then, referring to FIG. 12, FIG. 12 is a cross-sectional view of a leak-proof device according to a fifth embodiment of the disclosure when the leak-proof device is installed on the pipe.

The main difference between a leak-proof device 30d of this embodiment and the leak-proof devices of the previous embodiments is the structure of the fastener, and thus the follow paragraph mainly introduces a fastener 35d of the leak-proof device 30d.

In this embodiments, the fastener 35d of the leak-proof device 30d is, for example, a hose clamp including a ring body 351d and a screw 352d disposed on the ring body 351d. By tightening the screw 352d, the screw 352d can force the ring body 351d to fasten a confined layer 33d on the pipe 20.

Then, referring to FIG. 13, FIG. 13 is a cross-sectional view of a leak-proof device according to a sixth embodiment of the disclosure when the leak-proof device is installed on the pipe.

The main difference between a leak-proof device 30e of this embodiment and the leak-proof devices of the previous embodiments is the structure of the fastener, and thus the follow paragraph mainly introduces a fastener 35e of the leak-proof device 30e.

In this embodiment, the fastener 35e of the leak-proof device 30e is, for example, a C buckle. Two end portions of the fastener 35e are twisted and fixed each other so as to fasten a confined layer 33e on the pipe 20. In one embodiment, a protective layer (not shown) may be provided around the C buckle for preventing the end portions of the C buckle from hurting personnel.

According to the leak-proof devices, the liquid cooling systems and the electronic device as disclosed in the above embodiments, the confined layer of the leak-proof device is configured to (e.g., hermetically) surround and wrap the absorbent layer and a part of the leak detector and be fixed on the pipe, such that the confined layer can hold the liquid leaking from the place where the coupling portion of the pipe and the joint of the liquid cooling device for preventing the liquid from damaging electronic components (e.g., the motherboard).

In addition, the confined layer can hold the liquid leaking from the opening of the coupling portion of the pipe. Therefore, as long as one end of the leak detector sticks into a spaced enclosed by the confined layer and contacts the absorbent layer in this space, the leakage detection can be achieved. As a result, there is no need to wrap the leak detector at the place where the coupling portion of the pipe is assembled with the joint of the liquid cooling device, thereby saving the material cost of the leak detector.

Furthermore, the confined layer can hold the liquid leaking from the opening of the coupling portion of the pipe, and one end of the leak detector sticks into a spaced enclosed by the confined layer and contacts the absorbent layer in this space for achieving the leakage detection, and thus there is no need to arrange the leak detector around the liquid cooling device. Therefore, compared to a case that the leak detector is arranged around the liquid cooling device, the material cost of the leak detector can be reduced. Moreover, during the installation of the liquid cooling device, since there is no leak detector arranged around the liquid cooling device, the concern about damaging the leak detector no longer exists, thereby improving the installation efficiency.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A leak-proof device, configured to be mounted on a coupling portion of a pipe, comprising:
an absorbent layer, configured to be disposed on the coupling portion of the pipe;
a leak detector, in contact with the absorbent layer; and
a confined layer, configured to surround and wrap the absorbent layer and a part of the leak detector and be fixed to the pipe.

2. The leak-proof device according to claim 1, wherein a length and a width of the confined layer are greater than a length and a width of the absorbent layer.

3. The leak-proof device according to claim 1, wherein the absorbent layer comprises a base portion and a plurality of absorbent particles, and the plurality of absorbent particles are disposed in the base portion.

4. The leak-proof device according to claim 3, wherein a density of the plurality of absorbent particles at a place of the base portion located closer to the coupling portion of the pipe is smaller than a density of the plurality of absorbent particles at other places of the base portion.

5. The leak-proof device according to claim 4, wherein the base portion comprises an inner sub layer and an outer sub layer, the inner sub layer is surrounded by the outer sub layer and is located closer to the coupling portion of the pipe than the outer sub layer, and the plurality of absorbent particles are disposed in the outer sub layer.

6. The leak-proof device according to claim 4, wherein the base portion comprises a middle section and two side sections, the middle section is located between and connected to the two side sections, the middle section is configured to correspond to an opening of the coupling portion of the pipe, and the plurality of absorbent particles are disposed in the two side sections.

7. The leak-proof device according to claim 1, wherein the confined layer is made of an elastically deformable material.

8. The leak-proof device according to claim 1, wherein each of two opposite sides of the confined layer is provided with an adhesive layer, the leak-proof device further comprises two fasteners, and the two fasteners are respectively disposed on the two opposite sides of the confined layer.

9. A liquid cooling system, comprising:
a liquid cooling device, having a joint;
a pipe, having a coupling portion configured to be assembled with the joint; and
a leak-proof device, comprising:
an absorbent layer, configured to be disposed at a place where the coupling portion of the pipe is assembled with the joint of the liquid cooling device;
a leak detector, configured to be in contact with the absorbent layer; and
a confined layer, configured to surround and wrap the absorbent layer and a part of the leak detector and be fixed to the pipe and the joint.

10. The liquid cooling system according to claim 9, wherein in an extension direction of the pipe, a length of the confined layer is greater than a length of the absorbent layer.

11. The liquid cooling system according to claim 10, wherein in the extension direction of the pipe, two opposite sides of the absorbent layer are respectively spaced apart from two opposite sides of the confined layer.

12. The liquid cooling system according to claim 11, wherein the pipe is a round pipe, the length of the absorbent layer falls within a range from 1 to 3 times of a circumference of the pipe, and the length of the confined layer falls within a range from 1.5 to 2.5 times of the length of the absorbent layer.

13. The liquid cooling system according to claim 12, wherein a width of the confined layer falls within a range from 1.5 to 2.5 times of the circumference of the pipe, and a width of the absorbent layer is equal to the circumference of the pipe.

14. The liquid cooling system according to claim 12, wherein a thickness of the confined layer falls within a range from 0.01 cm to 0.3 cm, and a thickness of the absorbent layer falls within a range from 0.5 cm to a half of the circumference of the pipe.

15. The liquid cooling system according to claim 9, wherein the absorbent layer comprises a base portion and a plurality of absorbent particles, and the plurality of absorbent particles are disposed in the base portion.

16. The liquid cooling system according to claim 15, wherein a density of the plurality of absorbent particles at a place of the base portion located closer to the coupling portion of the pipe is smaller than a density of the plurality of absorbent particles at other places of the base portion.

17. The liquid cooling system according to claim 16, wherein the base portion comprises an inner sub layer and an outer sub layer, the inner sub layer is surrounded by the outer sub layer and is located closer to the coupling portion of the pipe than the outer sub layer, and the plurality of absorbent particles are disposed in the outer sub layer.

18. The liquid cooling system according to claim 16, wherein the base portion comprises a middle section and two side sections, the middle section is located between and connected to the two side sections, the middle section corresponds to an opening of the coupling portion of the pipe, and the plurality of absorbent particles are disposed in the two side sections.

19. The liquid cooling system according to claim 9, wherein each of two opposite sides of the confined layer is provided with an adhesive layer so as to be adhered on the pipe and the joint, the leak-proof device further comprises two fasteners, and the two fasteners are respectively disposed on the two opposite sides of the confined layer and fasten the confined layer on the pipe and the joint.

20. An electronic device, comprising:
a liquid cooling system, comprising:
a liquid cooling device, having a joint;
a pipe, having a coupling portion configured to be assembled with the joint of the liquid cooling device; and
a leak-proof device, comprising:
an absorbent layer, configured to be disposed at a place where the coupling portion of the pipe is assembled with the joint of the liquid cooling device;
a leak detector, configured to be in contact with the absorbent layer; and
a confined layer, configured to surround and wrap the absorbent layer and a part of the leak detector and be fixed to the pipe and the joint;
a motherboard; and
a baseboard management controller, wherein the leak detector is electrically connected to the baseboard management controller via the motherboard, and the leak detector is configured to transmit a leak signal to the baseboard management controller via the motherboard when detecting that the absorbent layer absorbs a liquid leaking from the coupling portion of the pipe.
